(19) United States
(12) Patent Application Publication
(10) Pub. No.: US 2008/0303033 A1
(43) Pub. Date: Dec. 11, 2008

(54) FORMATION OF NITRIDE-BASED OPTOELECTRONIC AND ELECTRONIC DEVICE STRUCTURES ON LATTICE-MATCHED SUBSTRATES

(75) Inventor: George R. Brandes, Raleigh, NC (US)

Correspondence Address: INTELLECTUAL PROPERTY / TECHNOLOGY LAW, PO BOX 14329, RESEARCH TRIANGLE PARK, NC, 27709, US

(73) Assignee: CREE, INC., Durham, NC (US)

(21) Appl. No.: 11/758,395

(22) Filed: Jun. 5, 2007

(51) Int. Cl. H01L 33/00; H01L 21/20

(52) U.S. Cl. 257/76; 438/47; 438/478; 257/E33.008; 257/E21.09

(57) ABSTRACT

A method of forming an AlInGaN alloy-based electronic or optoelectronic device structure on a nitride substrate and subsequent removal of the substrate. An AlInGaN alloy-based electronic or optoelectronic device structure formed on a nitride substrate is freed from the substrate on which it was grown.

### FIELD OF THE INVENTION

The invention relates generally to fabrication of nitride-based semiconductor devices. In particular, the invention relates to methods of forming aluminum indium gallium nitride (AlInGaN) alloy-based device structures on nitride substrates, and to electronic and optoelectronic device structures and device precursor structures grown by such methods.

### BACKGROUND OF THE INVENTION

Aluminum indium gallium nitride (AlInGaN) and related III-V nitride alloys are wide bandgap semiconductor materials that have application in optoelectronics (e.g., in fabrication of blue and UV light emitting diodes and laser diodes) and in high-frequency, high-temperature and high-power electronics. Formation of high-performance devices typically includes growth of high quality epitaxial films on a substrate.

AlInGaN alloy-based electronic and optoelectronic devices are typically grown on foreign (heteroepitaxial) substrates such as sapphire and silicon carbide (SiC). A primary consideration in selecting a substrate for growth of such devices is the degree of compatibility between the lattice structures of the substrate and the alloy layers grown thereon. Substantial differences in lattice structures and/or thermal expansion characteristics between a non-native substrate and device layers grown thereon can cause such device layers to have a high defect density (or “dislocation density”), which will detrimentally affect device performance.

In order to increase device performance, one approach has been to include spacer or buffer layers between the substrate and the active layers epitaxially grown thereon. Separation by such a spacer serves to distance active regions from high dislocation density substrate interface regions, and thus reduce the performance impact of dislocation defects on the active regions.

To further improve functionality of optoelectronic devices, it would be desirable to dispense with the use of such spacer layers, yet still yield AlInGaN-based devices having low dislocation densities, including devices adapted to provide short wavelength output.

Currently in the art, aluminum nitride (AlN) substrates are typically used for growth of AlInGaN-based devices. AlInGaN alloy-based epitaxial layers that are grown on low dislocation density AlN substrates result in short wavelength devices with lower dislocation densities than those grown on sapphire or SiC. It would be desirable, however, to develop additional substrates that enable fabrication of low dislocation density devices.

There remains a need in the art for alternative substrates to serve as growth templates for forming Group III nitride alloy-based (e.g. AlInGaN) electronic and optoelectronic device structures, and methods of forming the same. Such device structures should desirably have low dislocation densities. Needs also exist in the art for high efficiency electronic and optoelectronic devices with low dislocation densities, and for methods of making the same. Various embodiments of the present invention address these needs and provide additional advantages.

### SUMMARY OF THE INVENTION

The present invention relates to electronic and optoelectronic device structures and methods of making AlInGaN alloy-based electronic and optoelectronic device structures, in which AlInGaN alloy layers are deposited on or over a nitride substrate and the substrate is subsequently removed. The resulting device structures have high epitaxial layer quality and a dislocation density consistent with the dislocation density of the substrate.

In one aspect, the invention relates to a method of making an electronic or optoelectronic device structure, the method comprising the steps of: epitaxially growing one or more layers of an AlInGaN alloy on or over a nitride substrate to form a semiconductor device complex, and removing the substrate from the semiconductor device complex to form a resulting electronic or optoelectronic device structure. The resulting electronic or optoelectronic device structure is therefore devoid of the nitride substrate on which it was grown.

In another aspect, the invention relates to an electronic or optoelectronic device structure formed by the foregoing method. The resulting electronic or optoelectronic device has the benefit of being grown on a native nitride substrate, but is devoid of the substrate on which it was grown.

In still another aspect, the invention relates to a method of making an electronic or optoelectronic device structure, the method comprising the steps of epitaxially growing one or more layers of an AlInGaN alloy on or over a lattice-matched substrate to form a semiconductor device complex and removing the substrate from the semiconductor device complex to form a resulting electronic or optoelectronic device structure. The resulting electronic or optoelectronic device structure is therefore devoid of the substrate on which it was grown.

### BRIEF DESCRIPTION OF THE DRAWINGS

FIG. 1 illustrates a schematic cross-sectional view of a first semiconductor device complex formed according to a method of making an electronic or optoelectronic device structure, as described herein.

FIG. 2 illustrates a schematic cross-sectional view of a second semiconductor device complex formed according to a method of making an electronic or optoelectronic device structure, as described in Example 1 herein.

FIG. 3 illustrates a schematic cross-sectional view of a third semiconductor device complex formed according to a method of making an electronic or optoelectronic device structure, as described in Example 2 herein.

FIGS. 4A-4D illustrate schematic cross-sectional views of structures formed by executing steps of a method according to the present invention, as described in connection with Example 3 herein.

### DETAILED DESCRIPTION OF THE INVENTION

The present invention relates to improved methods of making electronic and optoelectronic device structures, including growth of one or more AlInGaN layers on a nitride substrate, which substrate is removed following growth of the device layers grown thereon. Optionally, the substrate may be reused. The invention also relates to electronic and optoelectronic device structures produced by methods according to the invention.

In one embodiment, a method of making an electronic or optoelectronic device structure comprises the steps of epitaxially growing one or more layers of an AlInGaN alloy on or over a nitride substrate to form a semiconductor device complex, and removing the substrate from the semiconductor device complex to form a resulting electronic or optoelectronic device structure. The resulting electronic or optoelectronic device structure is devoid of the nitride substrate on which it was grown.

In another embodiment, an electronic or optoelectronic device structure is formed by a method including epitaxially growing one or more layers of an AlInGaN alloy on or over a nitride substrate to form a semiconductor device complex, and removing the substrate from the semiconductor device complex to form a resulting electronic or optoelectronic device structure. The resulting electronic or optoelectronic device structure is devoid of the nitride substrate on which it was grown.

Still another embodiment relates to a method of making an electronic or optoelectronic device structure including epitaxially growing one or more layers of an AlInGaN alloy on or over a lattice-matched substrate to form a semiconductor device complex, and removing the substrate from the semiconductor device complex to form a resulting electronic or optoelectronic device structure. The resulting electronic or optoelectronic device structure is devoid of the lattice-matched substrate on which it was grown.

The term “nitride substrate” as used herein refers to a substrate at least a major portion of which is constituted by GaN, e.g., at least 60 weight percent (“wt %”) Ga, at least 70 wt % Ga, at least 75 wt % Ga, at least 80 wt % Ga, at least 90 wt % Ga, at least 95 wt % Ga, at least 99 wt % Ga, or 100 wt % Ga. Such a substrate may variously comprise, consist of or consist essentially of GaN. The substrate may be doped or undoped in character. In various embodiments, the substrate may, in addition to the major GaN portion, include other non-GaN III-V nitride components, such as AlN, AlInN, AlGaN, InN, InGaN, or AlInGaN, subject to stoichiometric restrictions as discussed below. The non-GaN portion of the substrate may be present in the form of one or more layers in the substrate, or otherwise as discrete regions or inclusions in the substrate material, or alternatively the substrate may be homogeneous with respect to the blended GaN and non-GaN components. As a still further alternative, the substrate may have a graded compositional character in one or more directions of the substrate article.

The term “gallium nitride” or “GaN” as used herein refers to either doped (e.g., n-type or p-type) or undoped gallium nitride.

As used herein, the term “AlInGaN alloy” refers to a nitride alloy selected from Group III metals, generally represented by the following: (Al, In, Ga)N or AlₓGa_{y}In_{1-x-y}N, where 0≦x≦1, 0≦y≦1 and x+y≦1. When identified herein by the general formula AlInGaN, the AlInGaN alloys are intended to be construed to encompass the any stoichiometrically appropriate ratio or amount (i.e., by variation of stoichiometric coefficients x and y) of each component in relation to the other components to yield stable alloy forms of AlInGaN. Similarly, AlGaN, InGaN, or AlInN, as used herein, refer to alloys with stoichiometrically appropriate ratios, that adhere to the above formula. Specifically, AlGaN refers to a nitride alloy that contains Al and Ga, InGaN refers to a nitride alloy that contains In and Ga, and AlInN refers to a nitride alloy that contains Al and In. The values of x and y need not be integers. Examples of such Group III nitride alloys include, but are not limited to alloys such as AlN, GaN, InN, Al_{0.3}Ga_{0.7}N, Al_{0.85}In_{0.15}N, In_{0.1}Ga_{0.9}N and Al_{0.1}In_{0.1}Ga_{0.8}N. Unless otherwise specified in the present specification, the term “AlInGaN alloy” also includes AlInGaN alloy mixtures, doped materials (e.g., n-type or p-type or compensated), and undoped materials.

Devices formed on a substrate in the broad practice of the present invention may be homoepitaxial or heteroepitaxial in relation to the substrate, and the device structure and the substrate may optionally have one or more layers therebetween, as interlayers of any suitable material that is compatible with the substrate and device structure.

As used herein the term “epitaxial” refers to an ordered crystalline growth on a crystalline substrate. When the crystals grown are the same of those of the substrate, the growth is “homoepitaxial” and when the crystals grown are different from those of the substrate, the growth is “heteroepitaxial.” The epitaxy referred to herein may be grown by any known epitaxial deposition method, including, but not limited to, chemical vapor deposition (CVD), metal-organic chemical vapor deposition (MOCVD), atomic layer epitaxy, molecular beam epitaxy (MBE), vapor phase epitaxy, hydride vapor phase epitaxy (HVPE), sputtering, and the like. Layers of a crystal generated by an epitaxial method are referred to herein as “epitaxial layers” or “epitaxial wafers.” Methods of forming (Al, In, Ga)N layers are described in U.S. Pat. No. 5,679,152, U.S. Pat. No. 6,156,581, U.S. Pat. No. 6,592,062, U.S. Pat. No. 6,440,823, and U.S. Pat. No. 6,958,093, all of which are incorporated herein by reference.

“Electronic” or “optoelectronic” device structures that can be formed by the methods of the invention include, but are not limited to, light emitting diodes (LEDs), laser diodes (LDs), high electron mobility transistors (HEMTs), heterojunction bipolar transistors (HBTs), metal semiconductor field-effect transistors (MESFETs), Schottky diodes, pn-junction diodes, pin diodes, power transistors, ultraviolet photodetectors, pressure sensors, temperature sensors, and surface acoustic wave devices, as well as other electronic and/or optoelectronics devices that can be advantageously fabricated on nitride substrates utilizing methods according to the present invention. In one embodiment of the invention, the electronic or optoelectronic device structure is embodied in an emitter diode. The emitter diode may emit a wavelength within the UV range. In another embodiment of the invention, the electronic or optoelectronic device structure is embodied in a non light-emitting electronic device.

Electronic or optoelectronic device structures formed by methods provided herein preferably comprise semiconductors that are semiconducting when exposed to electric fields, light, pressure and/or heat. An electronic or optoelectronic device structure formed by a method of the invention preferably includes an “active” region, which comprises one or more AlInGaN alloy layers.

Conventional electronic or optoelectronic device structures may include layers of active material formed by epitaxial deposition, with the initially deposited layer formed on a substrate serving as a growth template. A resulting wafer including the multilayer epitaxial structure may then be exposed to various patterning, etching, passivation and metallization techniques to form operable devices, and the wafer may be sectioned into individual semiconductor chips. Such chips may be subjected to further processing steps; for example, LED dies (chips) are typically packaged with one or more wirebonds, a reflector, and an encapsulant.

In selecting materials for the substrate and epitaxial layers of a semiconductor device complex, lattice constants and the potential for forming dislocations or other crystalline defects must be considered. Electronic or optoelectronic device structures with lower dislocation densities are generally desirable, as they enable high performance operation. In order to attain electronic or optoelectronic device structures with low dislocation densities, it is desirable to grow such structures on lattice-matched, low dislocation density substrates. Such substrates are challenging to produce and costly to obtain. The present invention relates to methods of forming electronic or optoelectronic device structures having low dislocation densities on nitride substrates with low dislocation densities. Nitride substrates utilized in the methods of the invention are subsequently removed, and if they are removed substantially intact, may be re-used.

Layers epitaxially grown on a low dislocation density substrate should be lattice-matched to the substrate. The matching of lattice constants between the substrate and epitaxially grown layers is important, as differing lattice constants cause strain in the layers and lead to defects in the formed semiconductor device complex. Additionally, alloys with well-matched lattice structures enable the formation of a low dislocation density semiconductor device complex with varying bandgaps between the layers.

Embodiments of the present invention provide an effective solution for forming an electronic or optoelectronic device structure with minimal strain between the substrate and the epitaxially formed layers. One embodiment relates to a method utilizing a low dislocation density nitride substrate to construct a highly lattice-matched semiconductor device complex including a nitride substrate and low dislocation density AlInGaN alloy epitaxial layers with minimized strain, as compared to formation of such epitaxial layers on an AlN substrate. Subsequent removal of the nitride substrate (which has a bandgap of only about 3.37 eV, and will strongly absorb radiation with wavelengths shorter than about 365 nm) prevents absorption of short wavelength light, which permits use of the resulting optoelectronic device structure in a broad range of applications. The nitride substrate may be advantageously removed to improve the performance of an electronic device. For example, removal of the substrate may reduce the overall voltage drop of a vertical device or may facilitate cooling by shortening heat transfer distance.

In one embodiment of the invention, material utilized in the epitaxially formed layers is composed of AlInGaN alloy(s). AlInGaN alloys provide versatility because bandgap and lattice constant characteristics can be varied. Similarly, AlGaN, AlInN and InGaN are desirable for use in the methods of the invention. In still another embodiment, the epitaxial layer material is selected from AlN and InN.

In one embodiment, the invention relates to a method of making an electronic or optoelectronic device structure, the method comprising the steps of:
epitaxially growing one or more layers of AlInGaN on or over a nitride substrate to form a semiconductor device complex; and
removing the substrate from the semiconductor device complex to form a resulting electronic or optoelectronic device structure,
wherein the resulting electronic or optoelectronic device structure is substantially devoid of the nitride substrate on which it was grown.

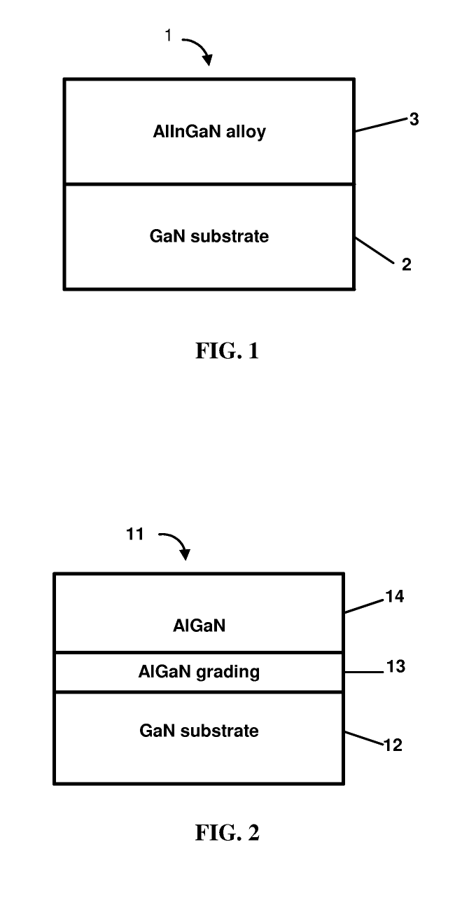

FIG. 1 illustrates a schematic cross-sectional view of a semiconductor device complex 1 formed according to a method of making an electronic or optoelectronic device structure, as described herein. Specifically, the semiconductor device complex 1 comprises a low dislocation density GaN substrate 2 and at least one AlInGaN alloy epitaxial layer 3. Following growth of the at least one epitaxial layer, the GaN substrate is removed as part of the processing to form a functional electronic or optoelectronic device structure devoid of the original substrate.

In one embodiment of the invention, the at least one AlInGaN alloy epitaxial layer is independently selected from AlInGaN, AlGaN, AlInN, InGaN, GaN, AlN and InN.

In one embodiment, the nitride substrate may be treated prior to addition of the epitaxial layer(s). Such treatment may include, for example, addition of a grading layer to the substrate surface. In one embodiment, an AlInGaN alloy grading layer is added to the nitride substrate. In another embodiment, the grading layer comprises AlGaN. Inclusion of such a grading layer provides a transition between the substrate and the epitaxial layers.

In one embodiment, the nitride substrate has a low dislocation density, preferably less than or equal to about 5×10⁷ cm⁻², more preferably less than or equal to about 1×10⁷ cm⁻², more preferably less than or equal to about 5×10⁶ cm⁻², and still more preferably less than or equal to about 1×10⁶ cm⁻².

In one embodiment, the resulting electronic or optoelectronic device structure comprises any of a diode, a transistor, a detector, an integrated circuit, a resistor, and a capacitor. In still another embodiment, the device comprises a light emitting diode or a laser diode. Such an emitter diode may emit light at a wavelength within the ultraviolet (UV), visible, or infrared (IR) spectra. In a preferred embodiment, UV emitters such as UV LEDs formed according to methods of the present invention are adapted to emit wavelengths of less than or equal to about 400 nm.

In still another embodiment of the invention, an electronic or optoelectronic device structure comprises a HEMT. Removal of the nitride substrate on which a HEMT or HEMY precursor structure was grown provides benefits as set forth above, including improved heat transfer and/or reduced voltage drop in a vertical device.

In still another embodiment, the resulting electronic or optoelectronic device structure has a dislocation density of preferably less than or equal to about 5×10⁷ cm⁻², more preferably less than or equal to about 1×10⁷ cm⁻², more preferably less than or equal to about 5×10⁶ cm⁻², and still more preferably less than or equal to about 1×10⁶ cm⁻², particularly in an active region of such structure.

According to various embodiments of the invention, a substrate is removed from a semiconductor device complex formed thereon. Removal of the substrate may also be referred to herein as separation or parting of the substrate. Removal, separation or parting of the substrate may be desirably carried out by modifying the interface between the substrate and the AlInGaN alloy epilayers. Such modification may be effected in any of a number of ways, including, but not limited to, any of: heating the interface, laser beam and/or focused light impingement of the interface, use of an interlayer or parting layer that facilitates parting, decomposing an interfacial material, generating gas at the interface, exposure of the interface to sonic energy, e-beam irradiation of the interface, radio frequency (rf) coupling to the interface, wet or dry etching, selective weakening of interfacial material, selective embrittlement of interfacial material, lateral fracturing at the interface region, and the like. Parting methods contemplated for use in methods according to the present invention therefore include any effective photonic, acoustic, physical, chemical, thermal or energetic processes, or combinations thereof, resulting in separation of the substrate from the electronic or optoelectronic device structure.

Chemical parting processes may include photodegradation of photosensitive interfacial material, which under photo-excitation conditions releases free radicals to catalyze an interfacial decomposition reaction, or chemical etching where the interfacial material is preferentially susceptible to an etchant introduced in the environment of the semiconductor device complex. Ion implantation may be used to create a weakened region for fracture within the semiconductor device complex.

In one embodiment, the method of substrate removal includes wet or dry etching. If removal is performed by etching, then an etchant that etches the substrate or a deposited “etch” layer may be used. Use of such an etch layer would allow etching of the etch layer, leaving the substrate and the device at least substantially intact. Additionally, an intermediate etch stop layer may be initially formed on the substrate, prior to formation of the at least one AlInGaN alloy layer, to prevent the etchant from effecting removal of the device layers. Such an etch stop layer may halt further etching entirely, or may slow the rate of etching.

In one embodiment, a method of substrate removal includes ion implantation in combination with a subsequent thermal process. According to such method, a layer of the semiconductor complex that has been implanted with ions (for example, hydrogen ions) via an ion implantation process, may be subjected to an elevated temperature separation step. In this step, the implanted ions build pressure in situ in or near the implanted layer to cause fracture of the substrate from the electronic or optoelectronic device structure formed thereon, thereby yielding the resulting electronic or optoelectronic device structure. Other ions utilized in such an implantation process for substrate removal may include, but are not limited to, helium ions.

A wide variety of methods for parting the substrate from the AlInGaN alloy will be apparent to those skilled in the art. Parting methods may be utilized alone or in combination. Parting methods are also described in U.S. Pat. No. 5,679,152, U.S. Pat. No. 6,156,581, U.S. Pat. No. 6,592,062, U.S. Pat. No. 6,440,823, and U.S. Pat. No. 6,958,093, all of which are incorporated herein by reference.

In a preferred embodiment of the invention, methods for removing the substrate comprise any of: grinding, wet etching, dry etching, optical separation, and ion implantation in combination with rapid thermal annealing (RTA). The removal technique chosen may depend on the type of device grown.

The term “remove” as used herein with reference to removal of the substrate form the device grown thereon refers to either complete removal of the substrate or to partial removal of the substrate. Preferably, substantially all of the substrate is removed. In one embodiment, substrate removal is effected such that less than 10 microns of the substrate remains on the device. In another embodiment, substrate removal is effected such that less than 1 micron of the substrate remains on the device

In one embodiment, the interface between the substrate and the AlInGaN alloy layers is rendered chemically reactive, such that the substrate interface can be easily parted from layers deposited thereon.

In various embodiments of methods according to the invention, a parting layer may be provided between the substrate and the overlying AlInGaN alloy layers. In one embodiment, the parting layer comprises InGaN. In an embodiment described in detail in Example 2, the semiconductor device complex may be exposed to photons, resulting in absorption of the photons by the InGaN layer, but not by the substrate or epitaxial layers. The bandgap characteristics of the various layers affect absorption by each layer. Optionally, the semiconductor device complex may also contain a carrier, in which case the photon exposure may be conducted from the side of the semiconductor device complex opposite the carrier. Additional nitride alloys may be utilized as such a parting layer.

Exemplary methods of the invention—including mechanical removal of the substrate from a LED via grinding (Example 1), optical separation of the substrate from a LED via photon bombardment of the complex (Example 2), and removal of the substrate from a LED via RTA after ion implantation (Example 3)—are set forth below.

Although the invention has been described with particular reference to a nitride substrate and AlInGaN alloy layers, including optional intermediate layers that may facilitate strain relief or parting of the substrate, the invention is not so limited. Electronic or optoelectronic device structures according to the present invention may also include further epitaxial layers, device structures, device precursors, other deposited materials, or devices made from such materials, so long as they do not preclude interfacial processing to effect separation of the nitride substrate. The aforementioned layers, structures, precursors, and materials may be deposited before or after the parting has been performed, as necessary and/or appropriate to the end use of the electronic or optoelectronic device structure. Systems containing these structures are also contemplated in the broad practice of the invention.

Advantages provided by removal of a substrate may depend on the type of electronic or optoelectronic device structure formed thereon. Such advantages may include, but are not limited to: increased light emission due to removal of absorbing layer(s), improved thermal management, increased light extraction or distribution due to altered optical path, improved electrical conductivity arising from contacting epilayers that may be more heavily doped or with narrower bandgap, and/or reduced voltage drop in a vertical device.

In another embodiment, an electronic or optoelectronic device structure comprises a thin LED attached to a carrier wafer. Such a carrier wafer may be added to the electronic or optoelectronic device structure. A carrier may be added to the top of the epitaxial layers on the semiconductor device complex, prior to separation of the substrate. Alternatively, a carrier wafer may be added after separation of the substrate. In one particular embodiment, an electronic or optoelectronic device structure comprises a thin LED, and a carrier wafer is added on top of the epitaxial layers of the semiconductor device complex prior to removal of the substrate. Such a carrier wafer is particularly advantageous when the device layers are thin (about ≦50 microns) and the wafer area is large (about >2 inches in diameter). The attached carrier wafer may be subsequently removed or the carrier wafer may remain attached indefinitely to the device layers, even after the device processing is completed and individual dies are produced.

Following removal of a substrate on which an electronic or optoelectronic device structure is grown, the resulting electronic or optoelectronic device structure is preferably a functional device. In one embodiment of the invention, a method further comprises treatment or further processing of the electronic or optoelectronic device structure after removal of the substrate, e.g., to optimize performance. The treatment may include any of: annealing after implant parting, chemical cleaning, grinding to roughen the surface, polishing to remove parting damage and smooth the surface, addition of a carrier, cutting into a chip or chips, and combining into a suitable package. If the resulting electronic or optoelectronic device structure comprises an LED, the LED may be combined with one or more phosphors and may incorporate materials transparent to the light emitted. In one embodiment, the electronic or optoelectronic device structure comprises a UV light emitting diode (LED).

Once a nitride substrate on which the electronic or optoelectronic device structure was grown is removed, the device may be subsequently mounted or otherwise attached to a substrate. Such an attached substrate may affect performance of the resulting electronic or optoelectronic device structure by optimizing, enhancing or even degrading that performance. In one embodiment, such a substrate may include any of silicon, diamond, sapphire, glass, copper, AlN, and GaN. In another embodiment, the attached substrate is of lower quality than the substrate on which the device was grown. An attached carrier wafer or newly attached substrate may facilitate heat removal or electrical conduction, for example.

In one embodiment of the invention, the removed substrate is substantially intact following the removal step. As such, the low dislocation density nitride substrate may be adapted for reuse in epitaxial layer growth. Reuse is preferable, as low dislocation density, high quality GaN-containing nitride substrates are difficult to fabricate and costly to obtain.

In another embodiment of the invention, the semiconductor device complex may be treated during formation. Such treatment may serve to manipulate the performance of the resulting electronic or optoelectronic device structure.

In another embodiment, a parting layer may be added to the semiconductor device between a nitride substrate and epitaxial layers of a device or device precursor grown thereon. In one embodiment, the parting layer comprises an AlInGaN alloy. In a further embodiment, the parting layer comprises InGaN or AlGaN.

In still another embodiment, a substrate may be thinned concurrent with the removal process.

Treatment of an electronic or optoelectronic device structure may include formation of vias. Such treatment provides improved (i.e., reduced) diode voltage drop in the resulting electronic or optoelectronic device structure.

In a still further embodiment, the invention relates to a method of making an electronic or optoelectronic device structure, the method comprising the steps of:
epitaxially growing one or more layers of an AlInGaN alloy on or over a lattice-matched substrate to form a semiconductor device complex; and
removing the substrate from the semiconductor device complex to form a resulting electronic or optoelectronic device structure,
wherein the resulting electronic or optoelectronic device structure is devoid of the substrate on which it was grown.

In one embodiment, the invention relates to a method of formulating a low dislocation density UV LED. Such method includes epitaxially growing one or more layers of an AlInGaN alloy on a homoepitaxial nitride substrate to form an UV LED on the substrate and separating the nitride substrate from the UV LED. The separated UV LED is a fully functional, low dislocation density UV LED devoid of the nitride substrate on which it was grown.

The following examples are intended to illustrate, but not limit the invention.

### EXAMPLE 1

### UV LED Grown on GaN Substrate and Substrate Removal by Grinding

A UV LED may be made by epitaxially growing AlₓGa_{y}N (where 0≦x≦1, 0≦y≦1 and x+y=1) layer(s) on a low dislocation density GaN substrate, with grading from GaN to AlGaN, to form a semiconductor device complex. The stoichiometry of the AlₓGa_{y}N alloy is chosen to be consistent with the wavelength of the emitter. Subsequently, the GaN may be ground away until the AlInGaN layer is reached. The resulting device, devoid of the GaN substrate, is an optoelectronic device structure useful as an UV LED.

An illustration of a schematic cross-sectional view of a first semiconductor device complex, prior to removal of the GaN substrate, is set forth in FIG. 2. Specifically, the semiconductor device complex 11 comprises a low dislocation density gallium nitride substrate 12, an AlGaN grading layer 13, and at least one AlGaN epitaxial layer 14, which forms the active region of the electronic or optoelectronic device structure.

### EXAMPLE 2

### UV LED Grown on GaN Substrate and Substrate Removal by Photon Exposure

A UV LED may be made by epitaxially growing AlₓGa₁₋ₓN layer(s) on a low dislocation density GaN substrate with an AlInGaN grading layer and an InGaN parting layer to form a semiconductor device complex. Subsequently, the complex is exposed to photons, from the front or the rear of the structure. If a carrier wafer is being used on top of the AlGaN layers, then illumination with photons must precede attachment with the carrier wafer or the carrier wafer must be transparent to the photons. Alternatively, photon exposure may be from the back of the complex, provided that the parting layer has a bandgap less than the substrate and grading layers (as in the case of a GaN substrate and an InGaN parting layer). The photons are absorbed by the InGaN parting layer, but not the GaN substrate or AlInGaN grading layers, causing separation of the GaN substrate and LED device structure at the InGaN parting layer.

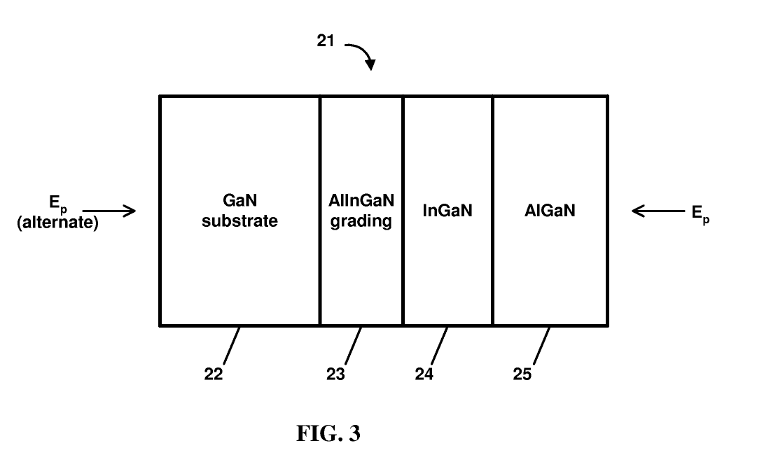

An illustration of a schematic cross-sectional view of a first semiconductor device complex, prior to removal of the GaN substrate, is set forth in FIG. 3. Specifically, the semiconductor device complex 21 comprises a low dislocation density gallium nitride substrate 22, an AlInGaN grading layer 23, a parting layer of InGaN 24 and at least one AlGaN epitaxial layer 25, which forms the active region of the electronic or optoelectronic device structure. The illustration shows the complex undergoing photon exposure from the front of the complex (i.e., through layer 25) or, optionally, from the back of the complex (i.e., through layer 22).

### EXAMPLE 3

### UV LED Grown on GaN Substrate and Substrate Removal by Ion Implantation and RTA

A UV LED may be made by epitaxially growing AlInGaN alloy layer(s) on a low dislocation density GaN substrate with an AlGaN grading layer to form a semiconductor device complex. The complex may be subsequently bombarded with monoenergetic H⁺ ions to implant such ions in the complex at a predetermined depth in the AlGaN layer. A carrier may be optionally added to the top of the epitaxial layer(s) of the semiconductor device complex. RTA may be used to fracture the complex along the line of the mean H⁺ implant depth, allowing removal of the GaN substrate from the LED. The backside of the LED may be cleaned and roughened and mounted to a substrate, if desired. The attached substrate is different from that on which the LED was grown. Once mounted, the LED and attached substrate may be annealed to remove any damage from the previous processes. The removed GaN substrate may be polished and reused for additional epitaxial layer growth processes.

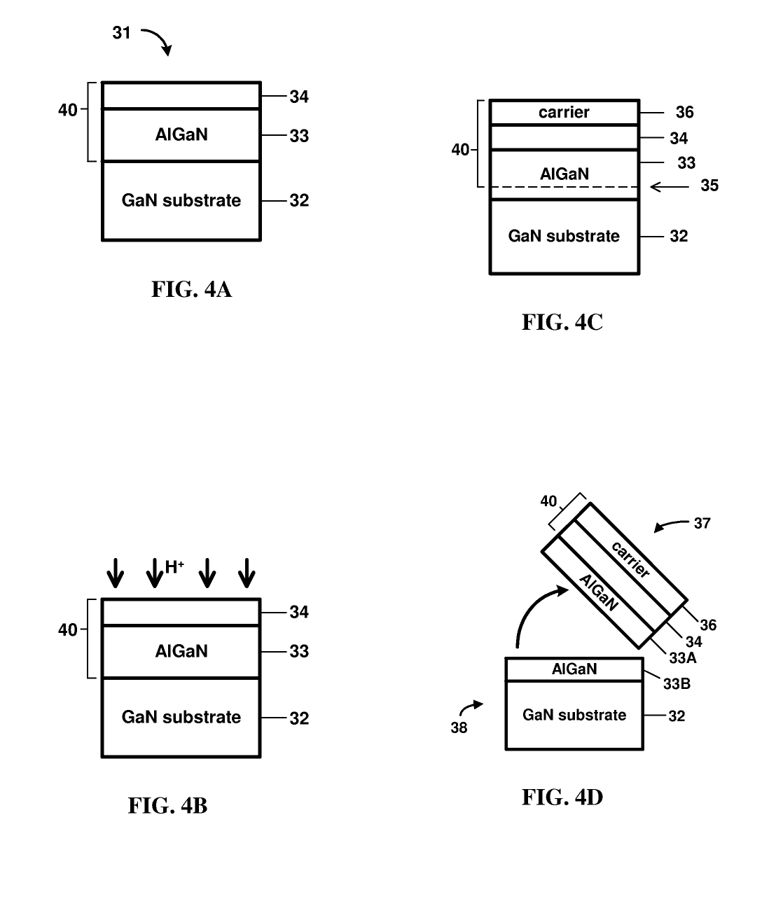

A schematic illustration of the method of Example 3 is set forth in FIGS. 4A-4D, showing cross-sectional views of structures (including intermediate products) formed in executing the steps of the Example. Specifically, FIG. 4A shows a semiconductor device complex 31 comprising a low dislocation density GaN substrate 32, a graded AlGaN layer 33, and at least one AlInGaN alloy epitaxial layer 34 to form a LED 40; FIG. 4B shows implantation of H+ions into semiconductor device complex 31; FIG. 4C shows semiconductor device complex 31 with mean implant depth 35 of the H⁺ ions implanted within the AlGaN layer 33 and an added carrier layer 36; and FIG. 4D shows fracture of semiconductor device complex 31 along the mean implant depth 35 within the AlGaN layer 33 into portions 33A and 33B to form a functional LED device 37 and a reusable low dislocation density GaN substrate 38.

### EXAMPLE 4

### HEMT Grown on GaN Substrate, and Substrate Removal by Grinding and Subsequent Mounting to a Diamond

A HEMT may be grown on a low dislocation density conducting GaN substrate. The HEMT is comprised of several microns of undoped GaN and is capped, for example, with 30 nm of 30% AlGaN. The HEMT structure is formable using a sequence of conventional device fabrication steps, known in the art and including, for example, patterning, etching, metal deposition, dielectric deposition and cleaning. Subsequent to growth of the HEMT, the GaN may be ground away or removed by any other suitable technique discussed above, and remounted to an insulating and thermally conductive substrate such as diamond. The resulting HEMT, devoid of the GaN substrate on which it was grown, is a low dislocation density, reduced gate leakage HEMT, able to operate at high power and high frequency.

Although the invention has been described with reference to the above examples, it will be understood that modifications and variations are encompassed within the spirit and scope of the invention. Accordingly, the invention is limited only by the following claims.

What is claimed is:

1. A method of making an electronic or optoelectronic device structure, the method comprising:
epitaxially growing one or more layers of an AlInGaN alloy on or over a nitride substrate to form a semiconductor device complex; and
removing the substrate from the semiconductor device complex to form a resulting electronic or optoelectronic device structure,
wherein the AlInGaN alloy and the nitride substrate comprise different materials and wherein the resulting electronic or optoelectronic device structure is devoid of the nitride substrate on which it was grown.

2. The method of claim 1, wherein the AlInGaN alloy is AlₓIn_{y}Ga_{1-x-y}N, wherein 0≦x≦1 and 0≦y≦1.

3. The method of claim 1, wherein the AlInGaN alloy is selected from any of AlGaN, AlInN, InGaN, AlN and InN.

4. The method of claim 1, wherein the nitride substrate comprises GaN.

5. The method of claim 1, wherein any of the nitride substrate and the resulting electronic or optoelectronic device structure has a dislocation density of less than or equal to about 5×10⁷ cm⁻².

6. The method of claim 1, wherein any of the nitride substrate and the resulting electronic or optoelectronic device structure has a dislocation density of less than or equal to about 1×10⁷ cm⁻².

7. The method of claim 1, wherein any of the nitride substrate and the resulting electronic or optoelectronic device structure has a dislocation density of less than or equal to about 5×10⁶ cm⁻².

8. The method of claim 1, wherein any of the nitride substrate and the resulting electronic or optoelectronic device structure has a dislocation density of less than or equal to about 1×10⁶ cm⁻².

9. The method of claim 1, wherein the electronic or optoelectronic device structure comprises any of a diode, a transistor, a detector, an integrated circuit, a resistor, and a capacitor.

10. The method of claim 9, wherein the electronic or optoelectronic device structure comprises a diode and is adapted to emit a wavelength of less than or equal to about 400 nm.

11. The method of claim 10, wherein the diode is an UV light emitting diode (LED).

12. The method of claim 1, wherein the electronic or optoelectronic device structure comprises a high electron mobility transistor (HEMT).

13. The method of claim 1, wherein the semiconductor device complex further comprises a parting layer.

14. The method of claim 1, wherein the substrate is removed by grinding.

15. The method of claim 1, wherein the substrate is removed by etching.

16. The method of claim 1, wherein the substrate is removed by optical separation.

17. The method of claim 1, wherein the substrate is removed by fracturing.

18. The method of claim 17, wherein the fracturing is performed by ion implantation and RTA.

19. The method of claim 1, wherein the removed substrate is substantially intact and adapted for reuse.

20. The method of claim 1, further comprising annealing the electronic or optoelectronic device structure after removal of the substrate.

21. The method of claim 1, further comprising chemically cleaning the electronic or optoelectronic device structure after removal of the substrate.

22. The method of claim 1, further comprising attaching a substrate to the electronic or optoelectronic device structure, wherein the attached substrate differs from the substrate on which the one or more AlInGaN alloy layers were grown.

23. The method of claim 22, wherein the attached substrate comprises any of silicon, diamond, sapphire, glass, copper or other metal, AlN and GaN.

24. The method of claim 1, further comprising attaching a carrier to the electronic or optoelectronic device structure.

25. The method of claim 24, wherein the carrier comprises any of silicon, diamond, sapphire, glass and copper.

26. The method of claim 24, wherein the carrier is added prior to removal of the substrate on which the one or more AlInGaN layers were grown.

27. The method of claim 24, wherein the carrier is added to the epitaxially grown layers.

28. The method of claim 1, further comprising defining vias in the device structure.

29. An electronic or optoelectronic device structure formed by the method of claim 1.

30. The electronic or optoelectronic device structure of claim 29, embodied in an emitter diode.

31. The electronic or optoelectronic device structure of claim 30, wherein the emitter diode is a UV LED.

32. The electronic or optoelectronic device structure of claim 29, embodied in a non light-emitting electronic device.

33. An electronic or optoelectronic device structure formed by a method comprising:
epitaxially growing one or more layers of an AlInGaN alloy on or over a nitride substrate to form a semiconductor device complex; and
removing the substrate from the semiconductor device complex to form a resulting electronic or optoelectronic device structure,
wherein the AlInGaN alloy and the nitride substrate comprise different materials and wherein the resulting electronic or optoelectronic device structure is devoid of the nitride substrate on which it was grown.

34. The electronic or optoelectronic device structure of claim 33, wherein the nitride substrate comprises GaN.

35. The electronic or optoelectronic device structure of claim 33, wherein any of the nitride substrate and the resulting electronic or optoelectronic device structure has a dislocation density of less than or equal to about 5×10⁷ cm⁻².

36. The method of claim 1, wherein any of the nitride substrate and the resulting electronic or optoelectronic device structure has a dislocation density of less than or equal to about 1×10⁷ cm⁻².

37. The method of claim 1, wherein any of the nitride substrate and the resulting electronic or optoelectronic device structure has a dislocation density of less than or equal to about 5×10⁶ cm⁻².

38. The method of claim 1, wherein any of the nitride substrate and the resulting electronic or optoelectronic device structure has a dislocation density of less than or equal to about 1×10⁶ cm⁻².

39. The electronic or optoelectronic device structure of claim 33, wherein the resulting electronic or optoelectronic device structure comprises any of a diode, a transistor, a detector, an integrated circuit, a resistor, and a capacitor.

40. A method of making an electronic or optoelectronic device structure, the method comprising:
epitaxially growing one or more layers of an AlInGaN alloy on or over a lattice-matched substrate to form a semiconductor device complex; and
removing the substrate from the semiconductor device complex to form a resulting electronic or optoelectronic device structure,
wherein the resulting electronic or optoelectronic device structure is devoid of the substrate on which it was grown.

41. The method of claim 40, wherein the lattice-matched substrate comprises GaN.
